(19) United States
(12) Patent Application Publication
(10) Pub. No.: US 2026/0122856 A1
(43) Pub. Date: Apr. 30, 2026

(54) SELECTIVE HEAT MANAGEMENT IN SEALED CHASSIS

(71) Applicant: QUANTA COMPUTER INC., Taoyuan City (TW)

(72) Inventors: Yi-Chieh CHEN, Taoyuan City (TW); Yueh-Chang WU, Taoyuan City (TW); Te-Chuan WANG, Taoyuan City (TW); Wei-Ju CHEN, Taoyuan City (TW)

(21) Appl. No.: 18/932,255

(22) Filed: Oct. 30, 2024

(51) Int. Cl. H05K 7/20; H05K 1/18

(52) U.S. Cl. CPC H05K 7/20436; H05K 1/181; H05K 7/20409; H05K 7/20509; H05K 2201/10151; H05K 2201/10522

(57) ABSTRACT

A fanless, sealed computer chassis for use in hot environments is disclosed. The chassis can include a chassis body having an outer wall and an inner wall. The outer wall can include external heat-dissipating features, such as fins. The chassis can include a dividing wall extending perpendicularly from the inner wall. A hot side of a thermoelectric cooler can be thermally coupled to the inner wall on one side of the dividing wall. A printed circuit board (PCB) can be secured to the chassis such that the dividing wall contacts the PCB (e.g., via a sealing layer) to divide the chassis' interior into a first enclosed space and a second enclosed space. The first enclosed space can include the thermoelectric cooler and one or more heat-susceptible components, while the second enclosed space can include one or more heat-tolerant components.

### TECHNICAL FIELD

The present disclosure relates to computing hardware generally and more specifically to heat dissipation technologies for sealed chassis.

### BACKGROUND

The fifth generation of mobile communication technology (5th generation wireless systems, referred to as 5G) is the latest generation of mobile communication technology, an extension of 4G (LTE) systems.

New 5G systems operate with higher transmission speeds than legacy 4G systems, and thus generate greater amounts of heat. Additionally, 5G base stations generally have substantially higher power consumption than legacy 4G systems (e.g., 2-3 times higher). Higher power consumption leads to greater heat generation. If a base station has poor heat dissipation, it will not only reduce work efficiency, but will also cause equipment problems such as damage, crashes, and disconnection of the network, all of which can seriously affect the user experience.

Current 4G base stations leverage a baseband unit (BBU) coupled to a remote radio unit (RRU). The BBU provides a physical interface with the 4G Core Network. The RRU couples to the BBU via a physical communication link and to one or more wireless devices via an antenna.

In 5G base stations, instead of a BBU, the base station makes use of a central unit (CU) and a distributed unit (DU). The CU and the DU each provide various radio processing and control functions. In 5G base stations, instead of an RRU and antenna, the base station makes use of an active antenna unit (AAU). The CU can be located at a more centralized location, while the DU and AAU can be distributed to various locations. The DU and AAU are often mounted in outdoor locations. As such, the DU and AAU must often have some minimal level of water ingress resistance, dust ingress resistance, and corrosion resistance.

The DU and AAU are often mounted in closed chassis that offer little to no airflow in and out of the chassis, relying on conduction through the system chassis itself to dissipate heat. Such a design is referred to as a fan-less design.

### BRIEF SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

Embodiments of the present disclosure include a computing system that includes a chassis. The chassis includes an inner wall and an outer wall. The outer wall includes one or more external heat-dissipating features. The computing system further includes a plurality of heat-generating computing components enclosed within the chassis. The plurality of heat-generating computing components includes at least one heat-susceptible component and at least one heat-tolerant component. The at least one heat-susceptible component has a maximum operating temperature lower than that of the at least one heat-tolerant component. The computing system further includes a dividing wall positioned within the chassis to separate the chassis into a first enclosed space and a second enclosed space, such that the at least one heat-susceptible component is located within the first enclosed space, and the at least one heat-tolerant component is located within the second enclosed space. The computing system further includes a thermoelectric cooler located in the first enclosed space. The thermoelectric cooler has a hot side and a cold side. The hot side is coupled to the inner wall of the chassis. The cold side is positioned at or adjacent to the at least one heat-susceptible component. The computing system further includes a thermal coupling material thermally coupling the cold side to the at least one heat-susceptible component.

The computing system may also include a scaling material coupling the dividing wall to a printed circuit board (PCB) upon which the at least one heat-susceptible component is mounted. In some cases, the dividing wall extends from the inner wall of the chassis. In some cases, the at least one heat-susceptible component includes a first heat-susceptible component having a first height defining a first gap between the first heat-tolerant component and the cold side of the thermoelectric cooler, and a second heat-susceptible component having a second height defining a second gap between the second heat-tolerant component and the cold side of the thermoelectric cooler, in which the first gap is greater than the second gap. In some cases, the chassis is fan-less.

In some cases, the plurality of heat-generating computing components are mounted on a printed circuit board (PCB) and the thermoelectric cooler is controlled by an electrical connection to the PCB. In some cases, the one or more external heat-dissipating features includes a plurality of fins integral with and extending from the outer wall.

In some cases, the sealing material is an adhesive capable of coupling the PCB to the dividing wall. In some cases, the dividing wall is integrally formed as part of the inner wall of the chassis. In some cases, the thermal coupling material includes a thermal gel capable of simultaneously bridging both the first gap and the second gap. The computing system may also include a thermal sensor positioned within the first enclosed space and configured to adjust power supplied to the thermoelectric cooler based on a sensed temperature within the first enclosed space.

Embodiments of the present disclosure include a computer chassis that includes a body having an inner wall and an outer wall. The computer chassis further includes one or more external heat-dissipating features positioned at the outer wall. The computer chassis further includes at least one mounting point for mounting a printed circuit board (PCB) to the body. The computer chassis further includes at least one dividing wall extending perpendicular from the inner wall to the PCB such that the at least one dividing wall separates the chassis into a first enclosed space and a second enclosed space when the PCB is mounted in the chassis. The at least one dividing wall is positioned such that at least one heat-susceptible component of the PCB is positioned in the first enclosed space and at least one heat-tolerant component of the PCB is positioned in the second enclosed space.

In some cases, the at least one dividing wall is integrally formed with the inner wall. In some cases, the inner wall includes a recess for receiving a thermoelectric cooler. The recess is located within the first enclosed space.

Embodiments of the present disclosure include a method. The method includes providing a computer chassis. The computer chassis includes a body having an inner wall and an outer wall. The computer chassis further includes one or more external heat-dissipating features positioned at the outer wall. The computer chassis further includes at least one dividing wall extending perpendicular from the inner wall. The method further comprises coupling a hot side of a thermoelectric cooler to the inner wall of the computer chassis. The method further comprises preparing a cold side of the thermoelectric cooler with a thermal coupling material and securing a printed circuit board (PCB) to the computer chassis. The PCB has a plurality of heat-generating computing components that include at least one heat-susceptible component and at least one heat-tolerant component. The at least one heat-susceptible component has a maximum operating temperature lower than that of the at least one heat-tolerant component. Securing the PCB to the computer chassis includes bringing the PCB to the at least one dividing walls to define a first enclosed space containing the thermoelectric cooler and the at least one heat-susceptible component. The at least one heat-tolerant component being positioned outside of the first enclosed space.

In some cases, coupling the hot side of the thermoelectric cooler to the inner wall includes adhering the hot side of the thermoelectric cooler to the inner wall using a thermally conductive adhesive. The method may also include preparing the at least one dividing wall with a sealing material prior to securing the PCB to the computer chassis, where when the PCB is secured to the computer chassis, the at least one dividing wall contacts the PCB via the sealing material. In some cases, the sealing material is an adhesive. The method may also include electrically coupling the thermoelectric cooler to the PCB via a cable.

In some cases, the at least one heat-susceptible component includes a first heat-susceptible component having a first height and a second heat-susceptible component where a second height is different than the first height. In some cases, the thermal coupling material is a thermal gel and securing the PCB to the computer chassis includes compressing the thermal gel to bridge both a first gap between the cold side of the thermoelectric cooler and the first heat-susceptible component and a second gap between the cold side of the thermoelectric cooler and the second heat-susceptible component.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE SEVERAL VIEWS OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a diagram depicting a radio system making use of a sealed computing system, according to certain aspects of the present disclosure.

FIG. 2 is a cutaway block diagram of a sealed computing system, according to certain aspects of the present disclosure.

FIG. 3 is a chart depicting temperatures of heat-susceptible components comparing a baseline solution with the improved solution, according to certain aspects of the present disclosure.

FIG. 4 is a chart depicting temperatures of heat-tolerant components comparing a baseline solution with the improved solution, according to certain aspects of the present disclosure.

FIG. 5A is a block diagram depicting average temperatures around a PCB without certain aspects of the present disclosure.

FIG. 5B is a block diagram depicting average temperatures around a PCB, according to certain aspects of the present disclosure.

FIG. 6 is a flowchart depicting a process for preparing a sealed computing system, according to certain aspects of the present disclosure.

### DETAILED DESCRIPTION

A fanless, sealed computer chassis for use in hot environments is disclosed. The chassis can include a chassis body having an outer wall and an inner wall. The outer wall can include external heat-dissipating features, such as fins. The chassis can include a dividing wall extending perpendicularly from the inner wall. A hot side of a thermoelectric cooler can be thermally coupled to the inner wall on one side of the dividing wall. A printed circuit board (PCB) can be secured to the chassis such that the dividing wall contacts the PCB (e.g., via a sealing layer) to divide the chassis' interior into a first enclosed space and a second enclosed space. The first enclosed space can include the thermoelectric cooler and one or more heat-susceptible components, while the second enclosed space can include one or more heat-tolerant components.

Placing a thermoelectric cooler (TEC) within a closed chassis for cooling purposes is initially counterintuitive. A TEC is capable of pumping heat from its cold side to its hot side, but requires energy to do so (e.g., input energy) and excess energy is released on the hot side. As a result, the hot side gets hotter than the cold side gets cold. In other words, the difference in temperature between a nominal temperature and the cold side is smaller than the difference in temperature between that nominal temperature and the hot side. Thus, use of a TEC within a closed chassis is counterintuitive because doing so would introduce additional generated heat within the chassis.

However, according to certain aspects and features of the present disclosure, a TEC can be placed within a closed chassis in a configuration that permits it to provide selective cooling to certain select components while minimally affecting other components within the chassis. In some cases, the select components can be components that are less heat-tolerant (more heat-susceptible). Thus, while the less heat-tolerant components (more heat-susceptible components) are being cooled by the TEC, additional heat generated due to use of the TEC may end up increasing the temperature of heat-tolerant components. Thus, the TEC can be driven to provide additional cooling to the heat-susceptible components as long as the excess heat generated by the TEC does not push the heat-tolerant components outside of their safe operating temperature rages.

As a result, computing devices making use of certain aspects and features of the present disclosure are able to withstand hotter external temperatures and are able to operate more efficiently and with less thermally-induced slow-down than competing computing devices. Further, the improved cooling abilities of the TEC can enable the design of chassis with more optimized fin sizes. Additionally, by eliminating the need for an interior fan, there are fewer or no moving parts that may need to be serviced, not only reducing maintenance costs, but also permitting the chassis to be designed in a fashion that would otherwise be impossible due to the need for maintenance access to fans. For example, in some cases, the chassis could be entirely sealed without any openable feature to provide maintenance access to the interior of the chassis.

In some cases, the TEC can be controlled by the very same PCB to which it is providing selective cooling. The TEC can be coupled to the PCB via a cable and corresponding connector on the board.

As described herein, the dividing wall extends from the chassis and contacts the PCB (e.g., directly or via a sealing layer) to delineate the first and second enclosed spaces. However, in some alternate embodiments, the dividing wall can be coupled to and can extend from the PCB such that when the PCB is installed in the chassis, the dividing wall contacts the inner wall of the chassis (e.g., directly or via a sealing layer).

As used herein, the term sealed computing system is intended to include computing systems that are enclosed within a housing that entirely or substantially limits the flow of air between the inside and outside of the housing, such as an airtight housing or a dustproof housing. In some cases, the housing may entirely or substantially limit the flow of fluid between the inside and outside of the housing, such as a waterproof housing. In some cases, the housing can have an Ingress Protection rating (IP rating) indicative of how well the housing keeps out various solids and/or liquids. For example, an IP rating of IP5X may be dust-protected to keep the ingress of dust low enough so that it doesn't affect the equipment inside, whereas an IP rating of IP6X may be dustproof such that no dust can ingress. In some cases, the sealed computing system may have an IP rating of at least IP2X, IP3X, IP4X, IP5X, or IP6X. As another example, an IP rating of IPX4 may provide protection against water splashing from any direction, whereas IPX7 may provide protection against water ingress when the housing is submerged for up to a minute. In some cases, the sealed computing system may have an IP rating of at least IPX2, IPX3, IPX4, IPX5, IPX6, IPX7, IPX8, or IPX9.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

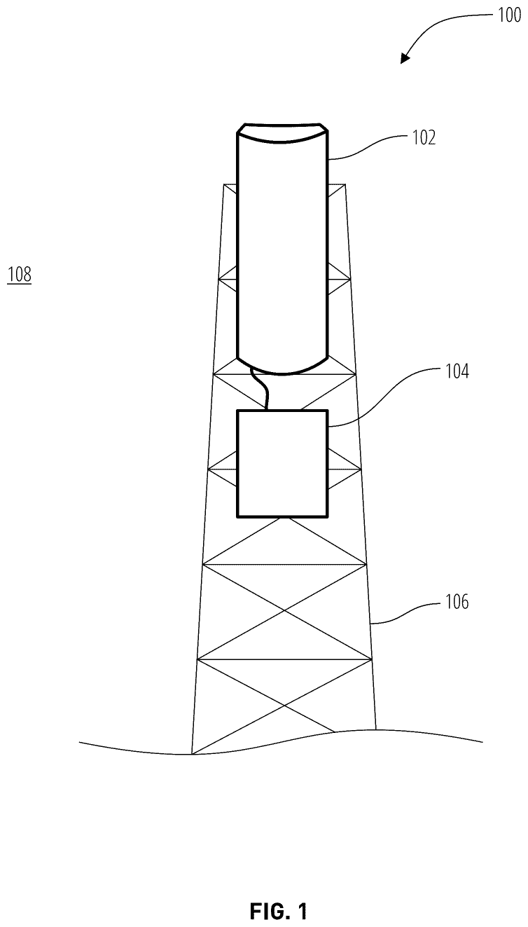

FIG. 1 is a diagram depicting a radio system 100 making use of a sealed computing system, according to certain aspects of the present disclosure. The radio system 100 can be mounted on a mast 106, although in some cases the radio system 100 can be mounted in other ways, such as to buildings. The radio system 100 can be positioned outdoors in an environment 108. While out in the environment 108, the radio system 100 can be subject to very high temperatures, such as due to ambient heat and direct sunlight, as well as rain and other weather events. As a result, components of the radio system 100 may need efficient cooling to continue operating as desired.

The radio system 100 can include an active antenna unit 102 coupled to a distributed unit 104. The distributed unit 104 can include various components located within a chassis, such as a PCB containing a CPU and various additional components. The distributed unit 104 can include a TEC within the housing, such as described in further detail herein.

The radio system 100 depicted in FIG. 1 is a 5G radio system, although certain aspects of the present disclosure can be used with other radio systems and other types of non-radio systems.

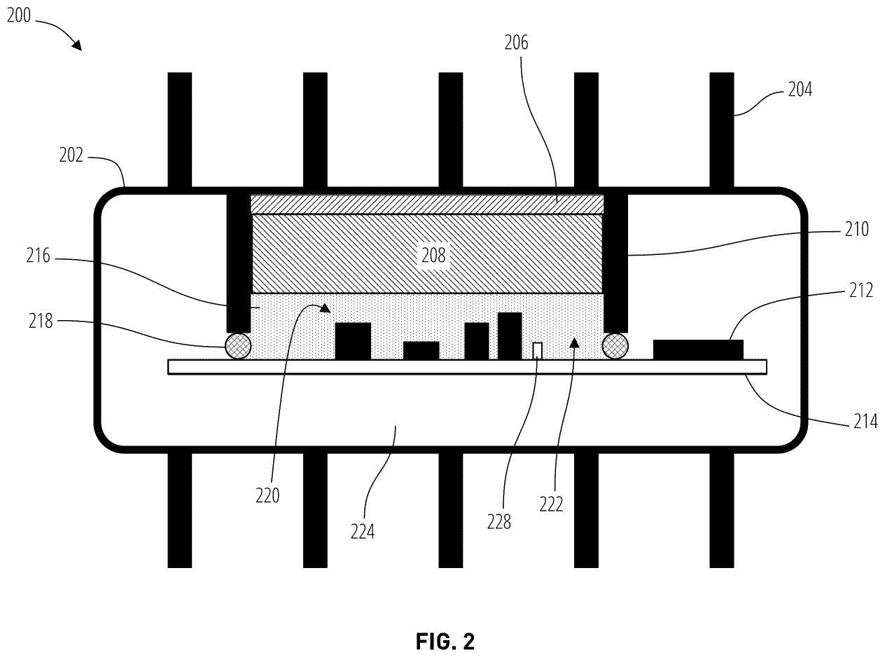

FIG. 2 is a cutaway block diagram of a sealed computing system 200, according to certain aspects of the present disclosure. The sealed computing system 200 can be distributed unit 104 of FIG. 1 or any other suitable sealed computing system. The sealed computing system 200 can be fanless.

The sealed computing system 200 can include a chassis 202. The chassis 202 can be made out of any suitable material. In some cases, the chassis 202 can be made from a thermally conductive material. The chassis 202 can include a number of fins 204 designed to dissipate heat from the components within the chassis 202 to the environment surrounding the chassis 202.

A PCB 214 can be positioned within the chassis 202 and can be mounted to the chassis 202 using any suitable mounting technique, such as being screwed into corresponding standoffs (not shown) extending from the inner wall of the chassis 202. The PCB 214 can include a number of components, including one or more heat-susceptible components 220 (e.g., various integrated circuits, such as to manage input/output ports, control the thermoelectric cooler 208, or perform functions) and at least one heat-tolerant component 212 (e.g., a central processing unit). Heat-susceptible components 220 can be any PCB-mounted or PCB-attached component that is less tolerant to high temperatures than the heat-tolerant component 212. In some cases, a heat-susceptible component 220 can have a temperature specification range that does not extend as high as that of a heat-tolerant component 212 on the same PCB 214.

The chassis 202 can include a dividing wall 210 extending away from an inner wall (e.g., inner surface) of the chassis 202. In some cases, the dividing wall 210 can be monolithic with the chassis 202, although in some cases the dividing wall 210 can be coupled to the chassis 202. The dividing wall 210 and the PCB 214 can separate the space within the chassis 202 into at least a first enclosed space 222 and a second enclosed space 224. Each enclosed space (e.g., the first enclosed space 222 and the second enclosed space 224) can be sealed from one another such that movement of fluid between the spaces is restricted or eliminated. The dividing wall 210 can extend for a suitable distance to contact the PCB 214 when the PCB 214 is installed in the chassis 202. The dividing wall 210 can directly contact the PCB 214, or more regularly can contact the PCB 214 through a sealing layer 218. The sealing layer 218 can seal the dividing wall 210 to the PCB 214 to completely or substantially restrict fluid movement between the first enclosed space 222 and the second enclosed space 224. The sealing layer 218 can be adhesive in nature (e.g., to adhere the PCB 214 to the dividing wall 210), although that need not always be the case. The sealing layer 218 can be a dispensable glue that, when cured, has sufficient elasticity to account for assembly tolerances.

The first enclosed space 222 can include the heat-susceptible components 220. A thermoelectric cooler 208 can be positioned in the first enclosed space 222. The thermoelectric cooler 208 can be secured to the inner wall of the chassis 202, such as via an adhesive layer 206. The adhesive layer 206 can be a thermally conductive adhesive. The thermoelectric cooler 208 can be positioned such that the hot side is coupled to the inner wall of the chassis 202 while the cold side is positioned facing the PCB 214.

A thermal coupling material 216 can be placed within the first enclosed space 222 such that heat generated by the heat-susceptible components 220 can be transferred to the cold side of the thermoelectric cooler 208, which can then pump the heat to the hot side of the thermoelectric cooler 208 and into the chassis 202 via the adhesive layer 206, where the heat can be dissipated into the environment surrounding the chassis 202 via the outer wall of the chassis 202 and/or the fins 204. The thermal coupling material 216 can fill any gaps between the thermoelectric cooler 208 and the heat-susceptible components 220, even if various heat-susceptible components 220 have different heights. Because of the sealing layer 218, the thermal coupling material 216 can remain within the first enclosed space 222 and does not egress into the second enclosed space 224. The thermal coupling material 216 can be a thermal gel. The thermal coupling material 216 can be any highly conforming thermal interface material. It can be important to ensure there are no gaps between the thermoelectric cooler 208 and the heat-susceptible components 220 (and the surrounding PCB 214) because air gaps adjacent the thermoelectric cooler 208 can cause damage to the thermoelectric cooler 208.

The second enclosed space 224 can include the at least one heat-tolerant component 212. Heat generated within the second enclosed space 224, such as by a heat-tolerant component 212, can pass, such as via convection, to the chassis 202 for dissipation into the surrounding environment.

In some cases, the presence of the thermoelectric cooler 208 within the chassis 202 can cause the second enclosed space 224 to be warmer when the thermoelectric cooler 208 is running than when the thermoelectric cooler 208 is off because the thermoelectric cooler 208 is itself a heat-generating component. Nevertheless, because the heat-susceptible components 220 are located within the first enclosed space 222, which is being actively cooled by the thermoelectric cooler 208, the heat-susceptible components 220 can maintain relatively lower (when compared to when the thermoelectric cooler 208 is not used) temperatures. Thus, as long as the heat-tolerant components 212 remain within specifications (e.g., at or below their maximum operating temperatures), the thermoelectric cooler 208 can be used to cool the heat-susceptible components 220.

In some cases, the chassis 202 can include a single thermoelectric cooler 208, although that need not always be the case. In some cases, the chassis 202 can include one or more dividing walls 210. In some cases, the one or more dividing walls 210 can separate the interior of the chassis 202 into more than two enclosed spaces, at least two of which are cooled by one or more thermoelectric coolers 208. In some cases, each enclosed space that is cooled by a thermoelectric cooler 208 can be cooled by a single thermoelectric cooler 208. In some cases, however, an enclosed space being cooled by a thermoelectric cooler 208 can be cooled by multiple thermoelectric coolers 208.

As shown in FIG. 2, the heat-tolerant component 212 and heat-susceptible components 220 are mounted on a single PCB 214. In some cases, any of the heat-tolerant components 212 and/or the heat-susceptible components 220 can be mounted on separate PCBs, or in some cases, not mounted to a PCB (e.g., separately mounted to the chassis 202). For example, in some cases the heat-susceptible components 220 being cooled by the thermoelectric cooler 208 are on a daughter board that is coupled, via a wired connection or a socket, to a motherboard containing the heat-tolerant component 212.

When a current is applied to the thermoelectric cooler 208, heat is absorbed at the cold side of the thermoelectric cooler 208 and then dissipated at the hot side. The amount of heat transferred in this manner is proportional to the amount of current applied.

In some cases, the thermoelectric cooler 208 can be actively controlled, in which case current supplied to the thermoelectric cooler 208 is controlled based on sensor data, such as sensor data from a temperature sensor 228. Such a temperature sensor 228 can be located in the first enclosed space 222. In some cases, a temperature sensor located elsewhere within the chassis 202 (e.g., in the second enclosed space 224) or outside of the chassis 202 (e.g., an ambient air temperature sensor located adjacent the chassis 202). In some cases, temperature data from an external source can be used, such as temperature data for a region in which the chassis 202 is located, as received from the Internet. In an example use case for a distributed unit 104 of a 5G radio system 100 (both in FIG. 1), a temperature sensor 228 can be located adjacent the heat-susceptible components 220 and the thermoelectric cooler 208 can be supplied with a 0.5A current when the sensed temperature is below 55° C., a 1A current when the sensed temperature is between 55° C. and 65° C., a 1.5A current when the sensed temperature is between 65° C. and 75° C., and a 2A current when the sensed temperature is above 75° C.

In some cases, the thermoelectric cooler 208 can be passively controlled, in which case a predetermined current is applied to the thermoelectric cooler 208. The proper predetermined current to apply can depend on the size of the thermoelectric cooler 208, the size of the first enclosed space 222, the size of the second enclosed space 224, the size of the chassis 202, and the amount of heat generated by the various heat-generating components within the chassis 202 (e.g., the heat-susceptible components 220 and the heat-tolerant components 212). To determine the proper current to apply, simulations can be run on an example sealed computing system. Different currents can be tested to determine the range in which the heat-susceptible components 220 remain below their respective maximum operating temperatures and the heat-tolerant components 212 remain below their respective maximum operating temperatures. As applied current increases, the temperature of the heat-susceptible components 220 will tend to go down, and the temperature of the heat-tolerant components 212 will tend to go up. In some cases, it can be desirable to use the lowest current at which the heat-tolerant components 212 and the heat-susceptible components 220 remain below their respective maximum operating temperatures. These simulations can be based on different ambient temperatures and/or other environmental conditions. The selection of current can be based on the most taxing ambient temperatures and/or other environmental conditions the sealed computing system 200 is expected to experience.

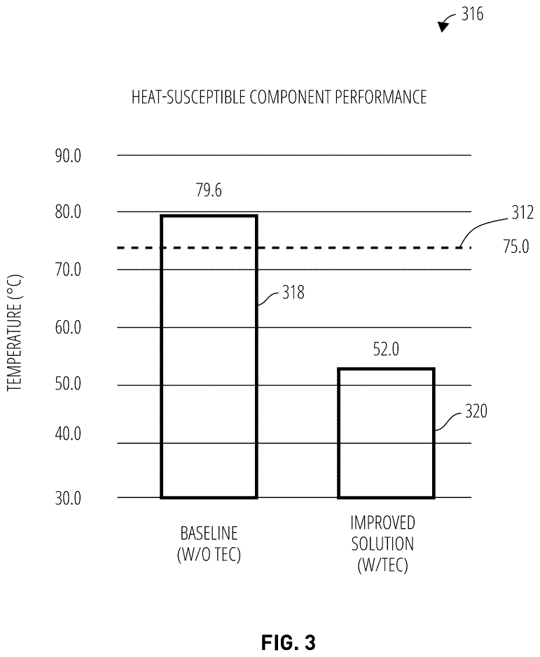

FIG. 3 is a chart 316 depicting temperatures of heat-susceptible components comparing a baseline solution with the improved solution, according to certain aspects of the present disclosure. The heat-susceptible components can be heat-susceptible components 220 of FIG. 2.

The baseline solution can be a fanless, sealed computing system without the use of a TEC. The improved solution can be a fanless, sealed computing system making use of a TEC as described herein, such as sealed computing system 200 of FIG. 2.

The heat-susceptible components can have a maximum operating temperature 312, such as at 75.0° C. The maximum operating temperature 312 can be defined by the manufacturer.

Chart 316 can depict the temperature reached by the heat-susceptible components when the sealed computing system is operated in a hot environment. As depicted in chart 316, the baseline solution 318 reaches temperatures above the maximum operating temperature 312, such as temperatures around 79.6° C. However, the improved solution 320 using TEC-cooling of a first enclosed space in which the heat-susceptible components are located keeps the heat-susceptible components at a relatively low temperature (e.g., 52.0° C.), far below the maximum operating temperature 312. It is clear that the use of a TEC and first enclosed space as disclosed herein can provide substantially improved thermal management to heat-susceptible components.

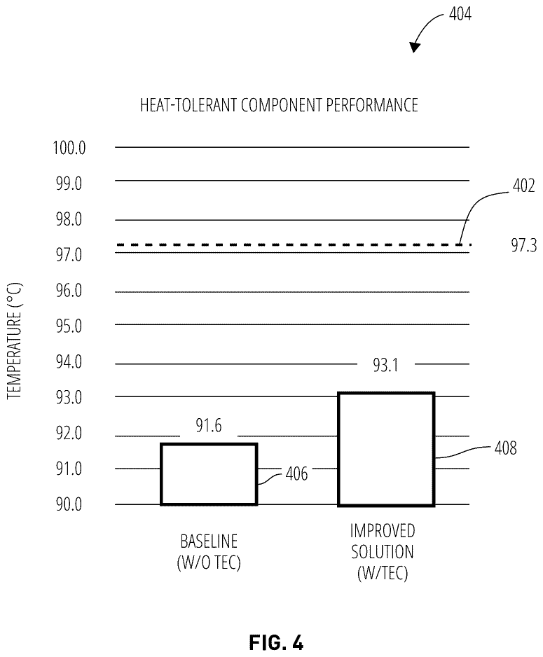

FIG. 4 is a chart 404 depicting temperatures of heat-tolerant components comparing a baseline solution with the improved solution, according to certain aspects of the present disclosure. The heat-tolerant components can be heat-tolerant components 212 of FIG. 2.

The baseline solution can be a fanless, sealed computing system without the use of a TEC. The improved solution can be a fanless, sealed computing system making use of a TEC as described herein, such as sealed computing system 200 of FIG. 2.

The heat-tolerant components can have a maximum operating temperature 402, such as at 97.3° C. The maximum operating temperature 402 can be defined by the manufacturer.

Chart 404 depicts the temperatures reached by the heat-tolerant components when the sealed computing system is operated in a hot environment. As depicted in chart 404, the baseline solution 406 reaches temperatures of only 91.6° C., which is well below the maximum operating temperature 312. The improved solution 320 reaches temperatures (e.g., 93.1° C.) that are higher than those of the baseline solution 406, but still well below the maximum operating temperature 402. Thus, the use of the improved solution can result in higher operating temperatures for the heat-tolerant components, but not enough adversely affect operation of the heat-tolerant components (e.g., not enough to push the heat-tolerant components out of specification).

Specifically, chart 404 represents the temperatures of the heat-tolerant components of the same baseline solution and the same improved solution disclosed with reference to chart 316 of FIG. 3. In other words, for the baseline solution, operation of the sealed computing system results in heat-susceptible components reaching temperatures of 79.6° C. and the heat-tolerant components reaching temperatures of 91.6° C.; and for the improved solution, operation of the sealed computing system results in heat-susceptible components reaching much lower temperatures of only 52.0° C., while the heat-tolerant components reach only slightly higher temperatures of 93.1° C.

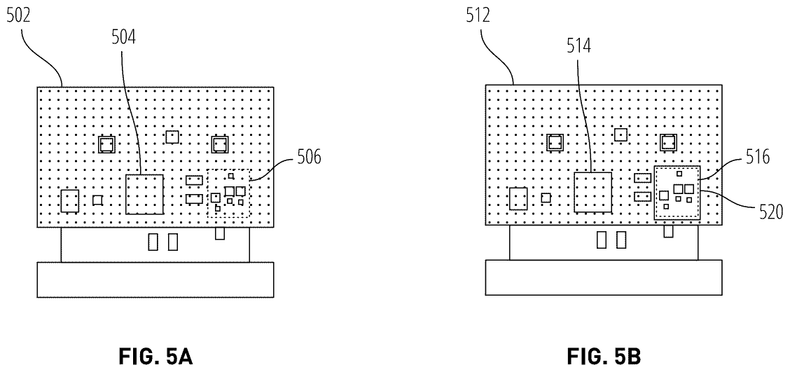

FIG. 5A is a block diagram depicting average temperatures around a PCB 502 without certain aspects of the present disclosure. PCB 502 includes a heat-tolerant component 504 and a set of heat-susceptible components 506. The sealed computing system in which the PCB 502 is used may be a baseline solution sealed computing system as described with reference to FIG. 3 and FIG. 4. For illustrative purposes, high temperatures are depicted generally by a pattern of dots.

As seen in FIG. 5A, the PCB 502 encounters high temperatures throughout, including at the heat-tolerant component 504 and the set of heat-susceptible components 506. These high temperatures might not exceed the maximum operating temperature for the heat-tolerant component 504, but may exceed the maximum operating temperatures for the set of heat-susceptible components 506.

FIG. 5B is a block diagram depicting average temperatures around a PCB 512, according to certain aspects of the present disclosure. PCB 512 includes a heat-tolerant component 514 and a set of heat-susceptible components 516. The sealed computing system in which the PCB 512 is used may be an improved solution sealed computing system as described with reference to FIG. 3 and FIG. 4. For illustrative purposes, high temperatures are depicted generally by a pattern of dots.

As seen in FIG. 5B, the PCB 512 encounters high temperatures throughout most of the PCB 512, including at the heat-tolerant component 514, but not at the set of heat-susceptible components 516, due to the use of a TEC and dividing wall 520, according to certain aspects of the present disclosure. The high temperature at the heat-tolerant component 514 might not exceed its maximum operating temperature, and the relatively lower temperatures at the set of heat-susceptible components 516 may be well-below the maximum operating temperatures for the set of heat-susceptible components 516.

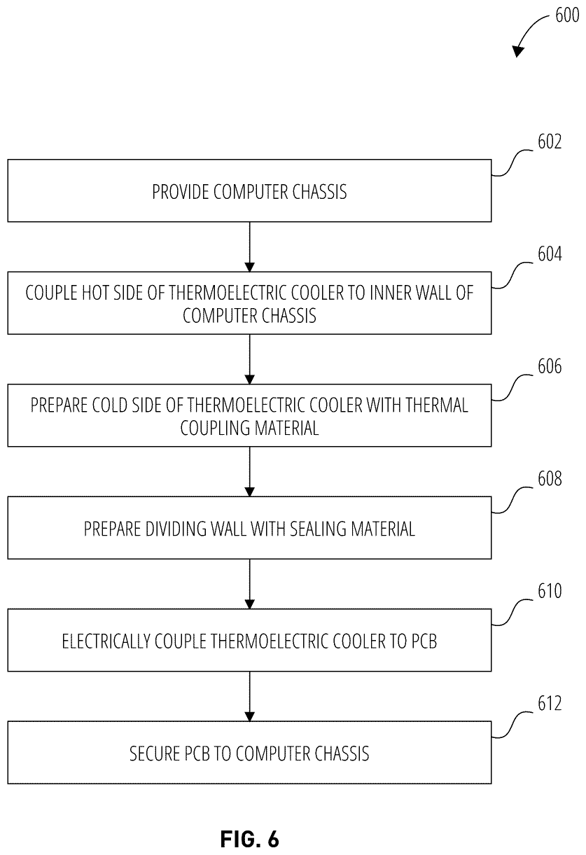

FIG. 6 is a flowchart depicting a process 600 for preparing a sealed computing system, according to certain aspects of the present disclosure. The sealed computing system prepared by process 600 can be sealed computing system 200 of FIG. 2.

At block 602, a computer chassis is provided. The computer chassis can be chassis 202 of FIG. 2.

At block 604, the hot side of a TEC can be coupled to the inner wall of the computer chassis from block 602. Coupling the hot side of the TEC to the computer chassis can include applying a thermal interface material to the TEC and/or the computer chassis prior to securing the TEC to the computer chassis (e.g., via fasteners, adhesives, or the like). In some cases, the thermal interface material is an adhesive.

At block 606, the cold side of the TEC can be prepared. Preparing the cold side can include applying thermal coupling material to the cold side of the TEC. This thermal coupling material can be any suitable material as disclosed herein, such as thermal gel. The amount of thermal coupling material applied at block 606 can be based on the calculated volume of the enclosed space in which the TEC will be placed, namely the volume of space between the cold side of the TEC and the PCB and its components.

At block 608, the dividing wall can be prepared with a sealing material. This scaling material can be any suitable material for sealing the gap between the dividing wall and the PCB when the PCB is installed in the chassis 202. In some cases, the sealing material is an adhesive. The sealing material, when cured, can remain sufficiently clastic to account for assembly tolerances. In some cases, the elasticity of the scaling material can ensure the thermal coupling material remains within its enclosed space when the PCB is coupled to the chassis 202, even if the amount of thermal coupling material minimally exceeds the available volume within the enclosed space. The sealing material forms the sealing layer 218 of FIG. 2.

At block 610, the TEC can be electrically coupled to the PCB. Electrically coupling the TEC to the PCB can include inserting a cable from the TEC into a corresponding receptacle of the PCB. For example, the TEC can be plugged into the PCB using any suitable connectors. In some cases, the TEC can be electrically coupled to the PCB by other means, such as by one or more spring-loaded pins that make contact with corresponding pads on the PCB during assembly.

At block 612, the PCB can be secured to the computer chassis. The PCB can be secured to the computer chassis using any suitable technique, such as through the use of screws, clips, adhesives, or the like. In some cases, the sealing material helps secure the PCB to the computer chassis, although that need not always be the case.

Process 600 includes the blocks depicted in FIG. 6. In some cases, some of the depicted blocks of process 600 can be excluded or combined. In some cases, process 600 can include additional blocks. In some cases, blocks of process 600 can be replaced with alternate blocks. As an example, in some cases process 600 can include blocks 602, 604, 606, 608, and 612, but not block 610. In such an example, the thermoelectric cooler may be electrically coupled to a component other than the PCB, such as an external power source or control board.

As another example, process 600 as seen in FIG. 6 involves the TEC being coupled to the chassis prior to the PCB being coupled to the chassis, but that need not always be the case. In such an example, instead of block 604, the process 600 could involve coupling the TEC to the PCB after block 606, then a new block could occur for preparing the hot side of the TEC (e.g., by applying the thermal interface material). In such an example, the hot side of the TEC would become thermally coupled to the chassis when the PCB is secured to the chassis at block 612.

The foregoing description of the embodiments, including illustrated embodiments, has been presented only for the purpose of illustration and description and is not intended to be exhaustive or limiting to the precise forms disclosed. Numerous modifications, adaptations, and uses thereof will be apparent to those skilled in the art. Numerous changes to the disclosed embodiments can be made in accordance with the disclosure herein, without departing from the spirit or scope of the disclosure. Thus, the breadth and scope of the present disclosure should not be limited by any of the above described embodiments.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system, comprising:
a chassis comprising an inner wall and an outer wall, the outer wall including one or more external heat-dissipating features;
a plurality of heat-generating computing components enclosed within the chassis, the plurality of heat-generating computing components including at least one heat-susceptible component and at least one heat-tolerant component, the at least one heat-susceptible component having a maximum operating temperature lower than that of the at least one heat-tolerant component;
a dividing wall positioned within the chassis to separate the chassis into a first enclosed space and a second enclosed space such that the at least one heat-susceptible component is located within the first enclosed space and the at least one heat-tolerant component is located within the second enclosed space;
a thermoelectric cooler located in the first enclosed space and having a hot side and a cold side, the hot side being coupled to the inner wall of the chassis, the cold side being positioned at or adjacent to the at least one heat-susceptible component; and
a thermal coupling material thermally coupling the cold side to the at least one heat-susceptible component.

2. The computing system of claim 1, further comprising a sealing material coupling the dividing wall to a printed circuit board (PCB) upon which the at least one heat-susceptible component is mounted.

3. The computing system of claim 2, wherein the sealing material is an adhesive capable of coupling the PCB to the dividing wall.

4. The computing system of claim 1, wherein the dividing wall extends from the inner wall of the chassis.

5. The computing system of claim 4, wherein the dividing wall is integrally formed as part of the inner wall of the chassis.

6. The computing system of claim 1, wherein the at least one heat-susceptible component includes:
a first heat-susceptible component having a first height defining a first gap between the first heat-tolerant component and the cold side of the thermoelectric cooler; and
a second heat-susceptible component having a second height defining a second gap between the second heat-tolerant component and the cold side of the thermoelectric cooler, the first gap being greater than the second gap.

7. The computing system of claim 6, wherein the thermal coupling material includes a thermal gel capable of simultaneously bridging both the first gap and the second gap.

8. The computing system of claim 1, wherein the chassis is fan-less.

9. The computing system of claim 1, wherein the plurality of heat-generating computing components are mounted on a printed circuit board (PCB), and wherein the thermoelectric cooler is controlled by an electrical connection to the PCB.

10. The computing system of claim 9, further comprising a thermal sensor positioned within the first enclosed space and configured to adjust power supplied to the thermoelectric cooler based on a sensed temperature within the first enclosed space.

11. The computing system of claim 1, wherein the one or more external heat-dissipating features includes a plurality of fins integral with and extending from the outer wall.

12. A computer chassis, comprising:
a body having an inner wall and an outer wall;
one or more external heat-dissipating features positioned at the outer wall;
at least one mounting point for mounting a printed circuit board (PCB) to the body; and
at least one dividing wall extending perpendicular from the inner wall to the PCB such that the at least one dividing wall separates the chassis into a first enclosed space and a second enclosed space when the PCB is mounted in the chassis, the at least one dividing wall being positioned such that at least one heat-susceptible component of the PCB is positioned in the first enclosed space and at least one heat-tolerant component of the PCB is positioned in the second enclosed space.

13. The computer chassis of claim 12, wherein the at least one dividing wall is integrally formed with the inner wall.

14. The computer chassis of claim 12, wherein the inner wall includes a recess for receiving a thermoelectric cooler, the recess located within the first enclosed space.

15. A method, comprising:
providing a computer chassis, the computer chassis comprising:
a body having an inner wall and an outer wall;
one or more external heat-dissipating features positioned at the outer wall; and
at least one dividing wall extending perpendicular from the inner wall;
coupling a hot side of a thermoelectric cooler to the inner wall of the computer chassis;
preparing a cold side of the thermoelectric cooler with a thermal coupling material; and
securing a printed circuit board (PCB) to the computer chassis, the PCB having a plurality of heat-generating computing components including at least one heat-susceptible component and at least one heat-tolerant component, the at least one heat-susceptible component having a maximum operating temperature lower than that of the at least one heat-tolerant component, wherein securing the PCB to the computer chassis includes bringing the PCB to the at least one dividing walls to define a first enclosed space containing the thermoelectric cooler and the at least one heat-susceptible component, the at least one heat-tolerant component being positioned outside of the first enclosed space.

16. The method of claim 15, wherein coupling the hot side of the thermoelectric cooler to the inner wall includes adhering the hot side of the thermoelectric cooler to the inner wall using a thermally conductive adhesive.

17. The method of claim 15, further comprising preparing the at least one dividing wall with a sealing material prior to securing the PCB to the computer chassis, wherein when the PCB is secured to the computer chassis, the at least one dividing wall contacts the PCB via the sealing material.

18. The method of claim 17, wherein the sealing material is an adhesive.

19. The method of claim 15, further comprising electrically coupling the thermoelectric cooler to the PCB via a cable.

20. The method of claim 15, wherein the at least one heat-susceptible component includes a first heat-susceptible component having a first height and a second heat-susceptible component having a second height that is different than the first height, wherein the thermal coupling material is a thermal gel, and wherein securing the PCB to the computer chassis includes compressing the thermal gel to bridge both a first gap between the cold side of the thermoelectric cooler and the first heat-susceptible component and a second gap between the cold side of the thermoelectric cooler and the second heat-susceptible component.
